(19) United States
(12) Patent Application Publication
(10) Pub. No.: US 2004/0036482 A1
(43) Pub. Date: Feb. 26, 2004

(54) Probe for use in level measurement in time domain reflectometry

(75) Inventor: Wayne Sherrard, Edmonton (CA)

Correspondence Address: MERCHANT & GOULD PC, P.O. BOX 2903, MINNEAPOLIS, MN, 55402-0903, US

(73) Assignee: Siemens Milltronics Process Instruments Inc., Peterborough (CA)

(21) Appl. No.: 10/449,461

(22) Filed: May 30, 2003

(30) Foreign Application Priority Data
May 31, 2002 (CA) 2,388,324

(51) Int. Cl. G01R 27/04; G01R 27/32

(52) U.S. Cl. 324/644

(57) ABSTRACT

A probe for sensing the level of a material or the interface between materials contained in a vessel using Time Domain Reflectometry measurement techniques. The probe comprises a primary conductive rod and at least two secondary conductive rods in spaced relationship with the primary conductive rod for reducing loss of TDR signals propagating through the probe.

### FIELD OF THE INVENTION

The present invention relates to level sensing, and more particularly to a probe structure for use in Time Domain Reflectometry (TDR)-based level sensing systems.

### BACKGROUND OF THE INVENTION

Time domain reflectometry (TDR) techniques are used to accurately detect and monitor the level of a contained material in level sensing systems. Such systems typically comprise a probe structure that, when immersed in a material contained in a storage vessel, behaves as a low quality transmission line for propagating TDR signals, and electronic circuitry to convey transmit pulses along the length of the probe and detect the reflected signals produced at the impedance changes in the probe. A transmit pulse propagating through the probe is reflected as it encounters a discontinuity in the electrical impedance of the probe caused by the change in the dielectric constant of the surrounding media. The time interval between an induced reference reflection and the transmit pulse is measured and used to ascertain the material level or determine other characteristic properties of the contained material.

A major limitation in the application of TDR techniques to level sensing relates to the design of the probe component. Known TDR probe structures suffer from loss of transmit pulses and reflected signals when detecting the level of materials having low dielectric constants. Conventional TDR level measurement systems often employ advanced signal processing schemes to improve detection of the reflected signals when measuring the level of media of low dielectric characteristics. However, these systems are generally complex, require precise calibration, and cannot be readily adaptable to a variety of level detection applications.

Known TDR probe architectures are also prone to clogging or sticking. A chunk or slug of material may clog the probe element, causing significant error in level detection. Sticking becomes problematic when a coaxial style probe is employed to detect the level of materials having a high dielectric constant, since such probe structures are often enclosed or have large surface area for the material to stick to. This can severely limit the sensitivity of the probe structure and result in erroneous level detection.

Thus there remains a need for TDR-based probe structures with enhanced accuracy and sensitivity and readily adaptable for use in a plurality of level sensing applications.

### BRIEF SUMMARY OF THE INVENTION

The present invention provides a probe component for use with TDR-based level sensing systems which improves the accuracy of detecting a return pulse corresponding to the change dielectric constant of the contained material.

In a first aspect, the present invention provides a probe for sensing the level of a material contained in a vessel using time domain reflectometry (TDR) techniques, the probe comprises: a primary conductive rod for conveying a TDR signal along the length thereof; and at least two secondary conductive rods in a parallel spaced relationship with the primary conductive rod.

In another aspect, the present invention provides a probe for sensing the level of a material contained in a vessel using time domain reflectometry, the probe comprises: a body having a conductive portion, and an insulated portion for securing the probe to the vessel; a primary rod in electrical communication with the conductive portion of the body for conveying a time domain reflectometry signal along the length thereof; and at least two secondary rods in parallel spaced relationship with the primary rod.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Reference will now be made to the accompanying drawings, which show, by way of example, embodiments of the present invention, and in which:

FIG. 1 is a schematic view of a TDR level sensing probe according to an embodiment of the present invention;

FIG. 2(a) is a schematic view of a TDR level sensing probe according to another embodiment of the present invention;

FIG. 2(b) is a schematic view of the bottom portion of the TDR level sensing probe of FIG. 2(a);

FIG. 2(c) is schematic view of the bottom portion of the TDR level sensing probe of FIG. 2(a) according to another embodiment of the invention; and

FIG. 3 is schematic view of a TDR-based level measurement system including a probe structure in accordance with the present invention.

### DETAILED DESCRIPTION OF EMBODIMENTS

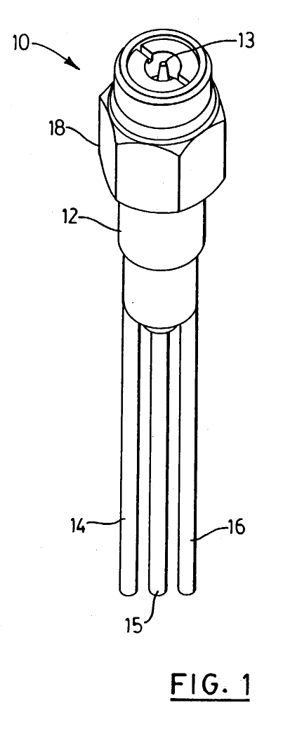

Reference is made to FIG. 1 which shows a level sensing probe 10 for sensing the level of a contained material or determining the interface level between two or more materials (including, for example, a liquid material, or a granular material) in a TDR-based level measurement system. In the drawings, like elements are designated by like reference numerals.

The level sensing probe 10 includes a primary conductive rod 15 formed from stainless steel, copper or other electrically conductive material and secondary conductive rods 14 and 16. The secondary rods 14, 16 are positioned in parallel along the opposite sides of the primary conductive rod 15. In an alternative embodiment, the conductive rods 15, 14, and 16 may be jointly held together in a layer of insulating material such as TEFLON™, PEEK™, NYLON™ or other similar materials, which runs along the entire length of the conductive rods 14, 15, and 16 in a tri-lead line configuration.

The probe 10 further includes a nonconductive body portion 12 which is sized to snugly fit within an opening in a vessel or container wall. The nonconductive body portion 12 includes a threaded portion about which a ring nut 18 is screwed for mounting the probe 10 against the wall of the vessel.

The primary rod 15, and the secondary conductive rods 14 and 16 are supported in an electrically isolated relationship within the nonconductive body portion 12 of the probe 10. The secondary conductive rods 14 and 16 are held at the same voltage potential level by, for instance, electrically shorting or coupling the secondary conductive rods 14 and 16 together. The exposed surface areas of conductive rods 14, 15, and 16 may be coated with an insulator to reduce corrosion and/or sticking of material onto the probe 10.

The conductive rods 14, 15, and 16 are sized to substantially match the effective impedance of an equivalent transmission line. The impedance is generally selected for maximum signal propagation along the probe 10.

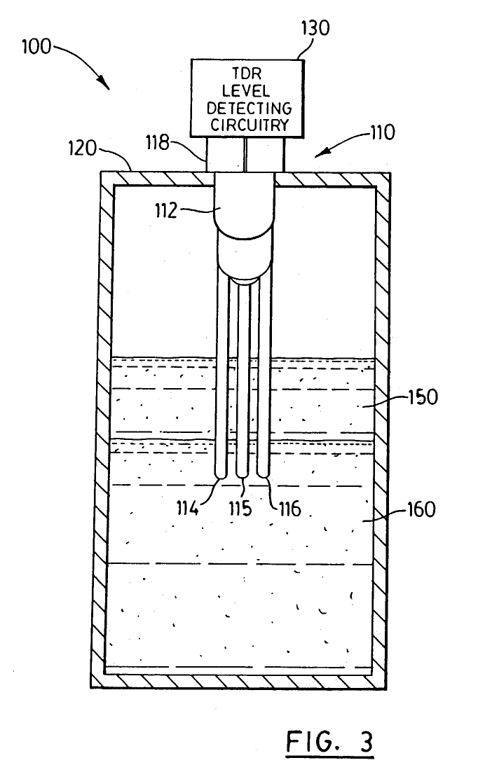

The primary conductive rod 15 is in electrical communication with TDR level detecting circuitry (for example 130 as shown in FIG. 3) via a signal lead 13 which extends through the nonconductive body portion 12. The TDR level detecting circuitry may comprise a pulse generator for launching incident pulses along the length of the probe 10, as well as a signal processing module comprising an AND converter and a microcontroller, suitably programmed using techniques apparent to one skilled in the art, for detecting and processing impedance changes in the probe 10 occurring at the interface between materials of different dielectric constants.

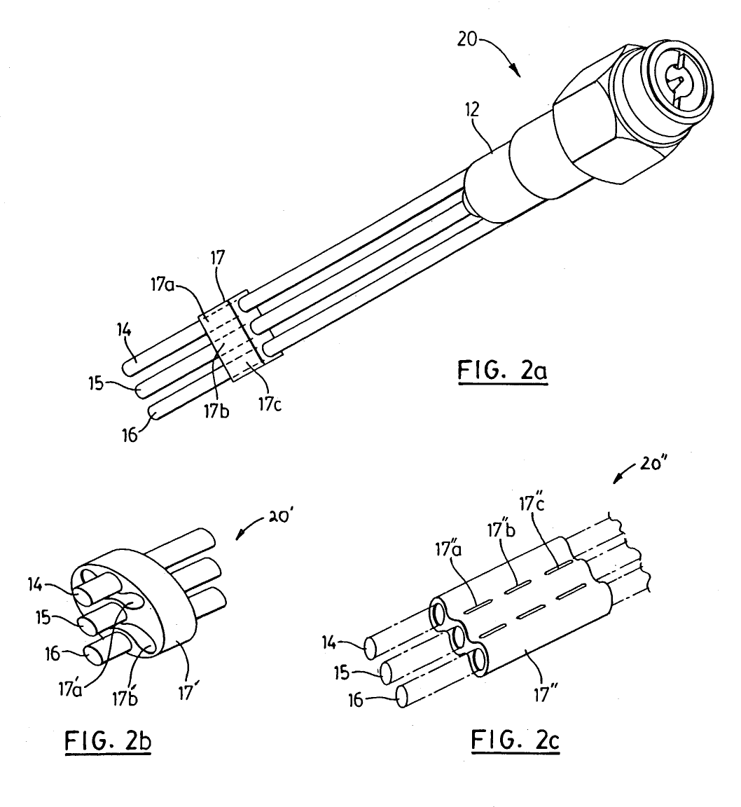

Reference is next made to FIG. 2(a) which depicts a probe structure 20 in accordance with another embodiment of the present invention. The probe structure 20 includes the primary elongated conductive rod 15 for conveying a TDR signal along the length thereof; and the secondary elongated conductive rods 14 and 16 arranged in a parallel spaced relationship with the primary conductive rod 15. The probe 20 further includes a spacer 17 to maintain a constant spacial relationship between the conductive rods 14,15, and 16 along the length of the probe 20. The spacer 17 includes bores 17a, 17b, and 17c having an inner diameter approximately equal to that of the conductive rods 14, 15, and 16. The bores 17a, 17b, and 17c receive the conductive rods 14, 15, and 16. In applications where the length of the probe 20 is substantially long, a plurality of spacers 17 may be employed. The design of the spacer 17 is generally optimized for improved structural support as well as to minimize signal reflection.

The spacer 17 is typically made of plastic polymers such as TEFLON™, PEEK™, NYLON™ or other similar nonconducting materials. However, in applications where the conductive rods 14, 15, and 16 are required to be electrically coupled together, the spacer 17 may be made of conducting material such as stainless steel, copper, or other similar conducting material to electrically connect the conductive rods 14, 15, and 16 at the distal end of the probe 20.

Reference is made to FIGS. 2(b) and 2(c) which show other embodiments of the probe structure 20. FIG. 2(b) shows a probe structure 20′ which includes a spacer 17′ defining perforations or apertures 17a′ and 17b′ substantially planar with the conductive rods 14, 15, and 16 to allow unobstructed rising or falling level of material inside the vessel. FIG. 2(c) shows a probe structure 20″ comprising a spacer 17″ with perforations or holes 17a″, 17b″, and 17c″ substantially perpendicular to the conductive rods 14, 15, and 16 to provide free movement of material inside the vessel.

Reference is next made to FIG. 3 which shows a probe-equipped TDR-based level measurement system 100 in accordance with the present invention for detecting the interface between materials 150, 160. The level measurement system 100 comprises a probe 110 adapted for being substantially immersed in a material contained in a storage vessel 120, for example, a silo, tank, open channel, or the like. The probe 110 is supported by an electrically isolated nonconductive body portion 112 configured to engage the walls of the vessel 120 in a sealed relationship. A ring nut 118 may be screwed on the body portion 112 or similar fastening means may be provided for securely mounting the probe 110 against the wall of the vessel 120. The probe 110 also includes a primary electrically conductive rod 115 for propagating TDR pulses within the material, and secondary conductive rods 114 and 116 positioned parallel along the opposite sides of the primary conductive rod 115 for detecting the interface between materials 150 and 160 using the TDR techniques.

The level measurement system 100 further includes TDR level detecting circuitry 130 electrically coupled to conductive rod 115 for performing TDR level monitoring. The TDR level detecting circuitry 130 may be located on the top wall (or the sidewall) of the vessel 120. In operation, the TDR level detecting circuitry 130 launches an incident pulse along the probe 110 and extending over the range of material levels being detected. When the material level inside the vessel 120 rises to a level at which the materials 150 and 160 surround the conductive rods 114, 115, and 116, the interface between the materials 150 and 160 causes impedance changes in the probe 110 as a result of different dielectric properties of the materials 150 and 160. The change in the probe 110 impedance in turn causes an amplitude and phase shift in a pulse reflected at the interface between the materials 150 and 160. This change in the amplitude and phase shift is detected by the TDR level detecting circuitry 130 and used to determine the location of the interface between the materials 150 and 160.

The present invention may be embodied in other specific forms without departing from the spirit or essential characteristics thereof. Although the present invention is generally described as a tri-rod configuration comprising a primary conductive rod and a pair of secondary rods, it may be appreciated that more secondary rods may be used for improved detection of the reflected pulse energy, thereby improving overall response and accuracy of the probe. Other adaptations and modifications of the invention will be obvious to those skilled in the art. Therefore, the presently discussed embodiments are considered to be illustrative and not restrictive, the scope of the invention being indicated by the appended claims rather than the foregoing description, and all changes which come within the meaning and range of equivalency of the claims are therefore intended to be embraced therein.

What is claimed is:

1. A probe for sensing the level of a material contained in a vessel using Time Domain Reflectometry (TDR), the probe comprising:
a primary conductor for conveying a TDR signal along the length thereof; and
at least two secondary conductors in a spaced relationship with said primary conductor.

2. The probe as claimed in claim 1, wherein said primary conductor and said secondary conductors are conductive rods.

3. The probe as claimed in claim 1, wherein said primary conductor and said secondary conductors are conductive metals selected from the group consisting of stainless steel and copper.

4. The probe as claimed in claim 1, wherein said primary conductor is positioned between said secondary conductors.

5. The probe as claimed in claim 1, wherein said primary conductor and said secondary conductors are arranged in a parallel spaced relationship.

6. The probe as claimed in claim 1, wherein said primary conductor and said secondary conductors are arranged in an electrically isolated relationship.

7. The probe as claimed in claim 1, wherein said primary conductor and said secondary conductors each have one end electrically coupled to one another.

8. The probe as claimed in claim 1, wherein said primary conductor and said secondary conductors are held together by a nonconductive body portion.

9. The probe as claimed in claim 1, wherein said primary conductor and said secondary conductors comprise flexible tri-lead lines.

10. The probe as claimed in claim 1, wherein said primary conductor and said secondary conductors each have a length, and the length of said primary conductor is substantially different than the length of said secondary conductors.

11. The probe as claimed in claim 1 further including a spacer, said spacer defining a plurality of bores for receiving said primary conductor and said secondary conductors to provide a spaced relationship between said primary conductor and said secondary conductors substantially along the length of the probe.

12. The probe as claimed in claim 11, wherein said spacer includes at least one aperture to permit unobstructed rising or falling level of liquid in the vessel.

13. A probe for sensing the level of a material contained in a vessel using time domain reflectometry, the probe comprising:
a body having a conductive portion, and an insulated portion for securing the probe to the vessel;
a primary rod in electrical communication with the conductive portion of said body for conveying a TDR signal along the length thereof; and
at least two secondary rods in spaced relationship with said primary rod.

14. The probe as claimed in claim 13, wherein said primary rod and said secondary rods are arranged in a parallel spaced relationship.

15. The probe as claimed in claim 13, wherein the conductive body portion of said body defines a signal lead coupled to said primary rod for communicating time domain reflectometry signals to said primary rod.

16. The probe as claimed in claim 13, wherein said primary and said secondary rods are arranged in an electrically isolated relationship.

17. The probe as claimed in claim 13, wherein said primary and said secondary rods are held together in an electrically insulating material.

18. The probe as claimed in claim 13, wherein said primary and said secondary rods comprise flexible tri-lead lines.

19. The probe as claimed in claim 13, wherein said insulated portion defines a plurality of openings for housing said primary and said secondary rods, so as to provide a spaced relationship between said primary and said secondary rods.

20. A level sensing system, comprising:
Time Domain Reflectometry (TDR) pulse generating means for launching an incident TDR pulse;
a primary conductive rod coupled to said TDR pulse generating means for conveying the incident TDR pulse through a medium;
at least two secondary conductive rods in spaced relationship with said primary conductive rod for detecting a reflected TDR pulse corresponding to said incident TDR pulse;
means for detecting said reflected TDR pulse; and
TDR level detecting means for determining a level reading for the medium based on said reflected TDR pulse.
